(19) United States
(12) Patent Application Publication
(10) Pub. No.: US 2004/0120395 A1
(43) Pub. Date: Jun. 24, 2004

(54) Digital pulse modulation arrangements

(76) Inventors: Raymond K. Orr, Kanata (CA); Yan-Fei Liu, Kingston (CA)

Correspondence Address: SMART & BIGGAR, 900-55 Metcalfe Street, P.O. Box 2999, Station D, Ottawa, ON, K1P 5Y6, CA

(21) Appl. No.: 10/733,322

(22) Filed: Dec. 12, 2003

Related U.S. Application Data
(60) Provisional application No. 60/433,031, filed on Dec. 13, 2002.

(51) Int. Cl. H03M 1/00; H03K 7/00

(52) U.S. Cl. 375/237; 375/239; 375/238

(57) ABSTRACT

A pulse modulation arrangement for a switch mode regulator includes a frequency controlled oscillator. A counter is enabled by a clock signal for the regulator to count a controlled number of output pulses of the oscillator and thereby produce a pulse modulation signal. The oscillator frequency and count number are controlled by digital and optionally analog feed forward and/or feedback control signals of the regulator. The oscillator can comprise binary weighted current sources and/or capacitors, or delay elements.

This application claims the benefit of U.S. Provisional Application No. 60/433,031 filed Dec. 13, 2002, the entire contents and disclosure of which are hereby incorporated herein by reference.

This invention relates to digital pulse modulation arrangements, examples of which are arrangements using PWM (pulse width modulation) in which the width or duration of pulses of a pulsed signal is modulated, PPM (pulse position modulation) in which timing of pulses of a pulsed signal is modulated, and PSM (phase shift modulation) in which a relative phase of a pulsed signal is modulated.

### BACKGROUND

As is known, pulse modulation can be used in a wide variety of applications, particularly open loop and/or closed loop control applications. Digital pulse modulation refers to pulse modulation in which there is at least one digital signal in dependence upon which the pulse modulation is controlled.

As one example, digital pulse modulation can be used for closed loop control of a switch mode power supply or regulator, which produces a regulated output voltage Vout from an input voltage Vin. A feedback loop of such a regulator can produce a digital control signal, representing an error voltage Verr, which is used to control the pulse modulation, which in this case is conveniently PWM or PSM, to maintain regulation of the output voltage.

A significant problem with digital pulse modulation is illustrated by the following example with respect to PWM.

For example, a buck regulator may use digital PWM to provide a regulated output voltage Vout of 5V±20% (i.e. in a range from 4V to 6V) with a resolution of 0.1% from an input voltage Vin of nominally 10V and variable from 7V to 15V (i.e. having a variation ratio of 15:7, or greater than 2:1), using a switching frequency Fs of 200 kHz and hence a switching period Ts of 5 μs. For nominally 10V input and for example 5V output, the duty cycle D (given by Vout/Vin) of the regulator is 0.5. Consequently, an ‘on’ time Ton for the PWM switching, equal to Ts multiplied by D, is 2.5 μs. To change the output voltage by one resolution step of 0.1%, e.g. from 5V to 5.005V, requires a 10-bit digital control signal to change the duty cycle D by 0.1% to 0.5005. Accordingly, the PWM ‘on’ time Ton must change to 2.5025 ps, this change also being by 0.1% or 2.5 ns. To provide this resolution of the PWM switching time requires a high digital PWM clock frequency of 400 MHz.

It can be appreciated that the required digital PWM clock frequency is further increased with finer resolution of the output voltage Vout, increasing switching frequency of the switch mode regulator, and decreasing duty cycle, so that in any particular case the digital PWM clock frequency may need to be at least several hundreds, or even thousands, of times the switching frequency. Specifically, the digital PWM clock frequency may be 2ⁿFs/Dmin, where the digital control signal has n bits for the required resolution and Dmin is a minimum value of the duty cycle D. The provision of such a high digital PWM clock frequency can be difficult or impractical.

This problem similarly applies to other forms of digital pulse modulation, such as digital PPM and PSM.

A need for improved digital pulse modulation arrangements is addressed by this invention.

### SUMMARY OF THE INVENTION

This invention provides a pulse modulation arrangement comprising a clock signal for determining a frequency of a pulse modulation signal and apparatus for determining a modulation parameter of the pulse modulation signal, the apparatus for determining a modulation parameter of the pulse modulation signal comprising a frequency controlled source responsive to a pulse modulation control signal.

Preferably the apparatus for determining a modulation parameter of the pulse modulation signal further comprises a counter for counting pulses produced by the frequency controlled source, and preferably the counter is controllable for counting a controlled number of pulses produced by the frequency controlled source for determining the modulation parameter of the pulse modulation signal. In particular, the pulse modulation control signal can comprise a digital control signal.

In an embodiment of the invention, the frequency controlled source comprises a plurality of binary weighted elements and a plurality of switches for selecting said binary weighted elements in dependence upon respective bits of said digital control signal. The binary weighted elements can comprise current sources and/or capacitors, or delay elements.

Preferably the frequency controlled source comprises at least one current source for providing a current with a magnitude controlled by a control signal.

Conveniently the modulation parameter comprises a pulse width or a phase shift of the pulse modulation signal.

The invention also provides a combination of a pulse modulation arrangement as recited above and a switch mode regulator controlled by the pulse modulation arrangement, wherein a switching clock of the switch mode regulator is derived from the clock signal for determining a frequency of the pulse modulation signal, and the pulse modulation control signal comprises a feedback control signal of the switch mode regulator.

The pulse modulation control signal can further comprise a feed forward control signal dependent upon an input voltage of the switch mode regulator. The feed forward control signal can comprise a digital signal or an analog signal.

### BRIEF DESCRIPTION OF THE DRAWINGS

The invention will be further understood from the following description by way of example with reference to the accompanying drawings, in which the same references are used in different figures to denote similar elements and in which:

FIG. 1 schematically illustrates a known digital PWM arrangement;

FIG. 2 schematically illustrates a digital PWM arrangement in accordance with an embodiment of this invention;

FIG. 3 schematically illustrates one form of frequency controlled oscillator which may be used in the arrangement of FIG. 2;

FIGS. 4 and 5 illustrate modifications of the frequency controlled oscillator of FIG. 3;

FIG. 6 schematically illustrates a modified form of frequency controlled oscillator which may be used in the arrangement of FIG. 2;

FIG. 7 schematically illustrates a voltage-to-current converter which may be used in a frequency controlled oscillator;

FIG. 8 schematically illustrates another form of frequency controlled oscillator which may be used in the arrangement of FIG. 2; and

FIG. 9 schematically illustrates a digital PSM arrangement in accordance with another embodiment of this invention.

### DETAILED DESCRIPTION

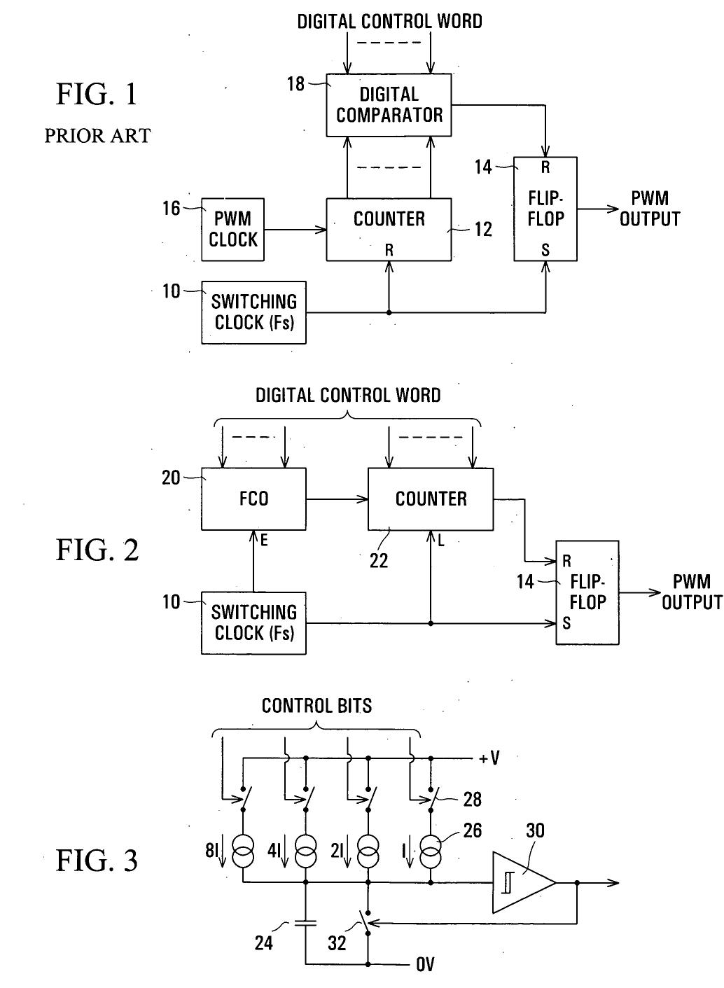

Referring to the drawings, FIG. 1 illustrates one example of a known digital PWM arrangement which comprises a source 10 for a switching clock of a switch mode regulator (not shown) to be controlled by the digital PWM arrangement, having a frequency Fs which typically may be in a range from 100 kHz to 500 kHz or more and for example is 200 kHz. In addition, the arrangement comprises a counter 12, a set-reset flip-flop 14 which produces a PWM control signal at its output, a PWM clock source 16, and a digital comparator 18.

In operation of the arrangement of FIG. 1, the switching clock source 10 produces narrow pulses at the frequency Fs each of which serves to reset the counter 12 via a reset input R of the counter, and to set the flip-flop 14 via a set input S of the flip-flop. The digital comparator 18 compares the count of the counter 12 with a digital control word, and when the digital comparator 18 detects a match it produces an output which resets the flip-flop 14 via a reset input R of the flip-flop. Consequently, the output of the flip-flop 14 is a PWM signal at the frequency Fs and with a duty cycle determined by the digital control word, which for example is supplied by the switch mode regulator in a closed loop for regulating an output voltage of the regulator.

As described above, the resolution of the digital PWM arrangement of FIG. 1 is dependent upon the frequency of the PWM clock 16, which must be many times greater than the switching clock frequency Fs. For example, for the 0.1% resolution discussed above, the counter 12 may be a 10-bit counter, the digital comparator 18 may be a 10-bit comparator, and with Fs=200 kHz the frequency of the PWM clock 16 may be 400 MHz. A similar difficulty of requiring a very high PWM clock frequency applies for various other known forms of digital PWM arrangement, the arrangement of FIG. 1 being given only by way of example.

FIG. 2 illustrates, by way of example, a digital PWM arrangement in accordance with one embodiment of this invention. The digital PWM arrangement of FIG. 2 comprises the switching clock source 10 and flip-flop 14 arranged in a similar manner to that of FIG. 1. Instead of the counter 12, PWM clock 16, and digital comparator 18 of FIG. 1, the PWM arrangement of FIG. 2 comprises a frequency controlled oscillator (FCO) 20 and a counter 22. The FCO 20, shown as being enabled by the clock source 10 via an enable input E of the FCO, produces at its output a pulsed signal pulses of which are counted by the counter 22.

For example, the counter 22 can be a down counter which counts down from a preset count, constituted by only some of the bits of the digital control word, with which the counter 22 is loaded in response to each pulse of the switching clock being supplied to a load input L of the counter 22. On reaching (or on under-flow from) a zero count, the counter 22 produces an output which resets the flip-flop 14 via its reset input R. Other bits of the digital control word are supplied as a digital control input to the FCO 20, to control the frequency of pulses produced at its output. Thus the bits of the digital control word are distributed for control of the counter 22 and the FCO 20, and the duty cycle of the PWM output from the flip-flop 14 is dependent upon both the frequency of pulses produced by the FCO 20 and the count with which the counter 22 is preset.

It can be appreciated that, instead of the counter 22, the digital PWM arrangement of FIG. 2 can alternatively include a digital comparator 18 and a counter 12, in a similar manner to that of the arrangement of FIG. 1 but with only some of the bits of the digital control word supplied to the digital comparator.

For example, to provide a resolution of 0.1% for the duty cycle of the PWM output from the digital PWM arrangement of FIG. 2 (and hence a resolution of 0.1% for a consequently regulated voltage of a switch mode regulator controlled by the PWM arrangement), a 10-bit digital control word can be provided, the bits of this control word being distributed in a desired manner between the FCO 20 and the counter 22. For example, the FCO 20 may be supplied with the five least significant bits of the digital control word, and the counter 22 may be a 5-bit counter supplied with the five most significant bits of the digital control word.

Accordingly, in this case the pulsed output of the frequency controlled oscillator 20 has a frequency of the order of 2⁵, or 32, times the switching clock frequency Fs, e.g. of the order of 6.4 MHz for a frequency Fs of 200 kHz. Such a frequency can be provided much more easily by the FCO 20 than can be the high frequency of 400 MHz required of the PWM clock for the same PWM output resolution in the known digital PWM arrangement of FIG. 1.

It can be appreciated that the distribution of the bits of the digital control word, frequencies, and other parameters given above are provided only by way of example and may be varied as may be desired. In particular, the total number of bits of the digital control word, and the manner in which these are distributed between the FCO 20 and the counter 22, can be changed. For example, a smaller number of bits can be used to control the counter 22, which accordingly can have a correspondingly smaller number of bits. Conceivably, the counter 22 can be eliminated entirely, the entire digital control word serving to control the FCO 20. Furthermore, although the above description refers to a digital control word, control may be provided and/or facilitated by a combination of analog and digital control, for example as further described below.

The frequency controlled oscillator 20 can have any desired form, some examples of which are described below.

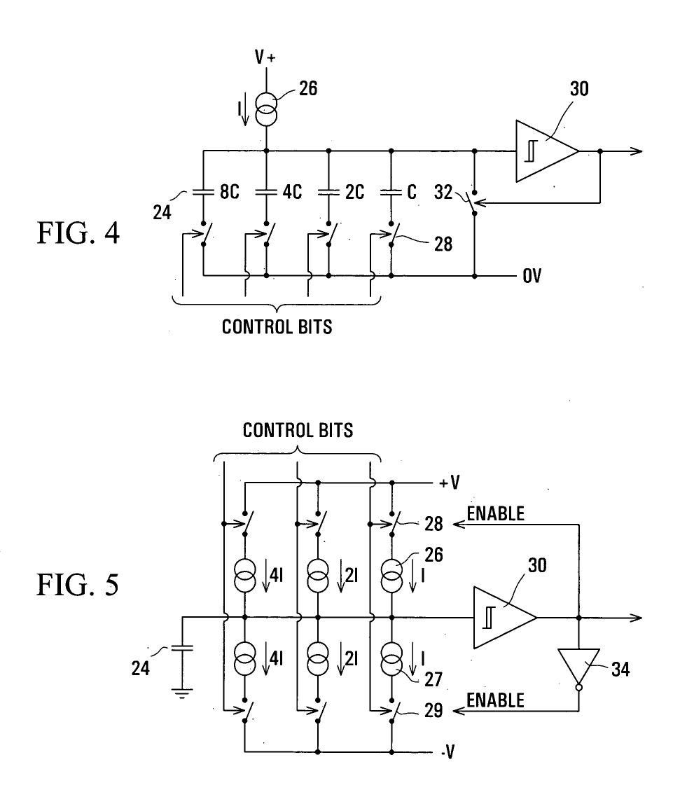

FIG. 3 illustrates one form of frequency controlled oscillator which may be used in the arrangement of FIG. 2. Referring to FIG. 3, the converter comprises a capacitor 24 arranged to be charged via selected ones of a plurality of, four as illustrated, current sources 26 providing binary weighted currents I, 2I, 4I, and 8I respectively, the charging current being selected by a corresponding plurality of switches 28 controlled by respective bits of the digital control word. The voltage to which the capacitor is charged is compared with a threshold by a voltage comparator 30. An output of the comparator 30 controls a switch 32 to discharge the capacitor 24, and constitutes the pulsed output of the frequency controlled oscillator.

FIG. 4 illustrates a modification of the frequency controlled oscillator of FIG. 3, in which instead of there being a single capacitor 24 and a plurality of binary weighted current sources 26 with respective selection switches 28, there is a single current source 26 and a plurality of capacitors 24 having binary weighted capacitances C, 2C, 4C, and 8C selected by respective ones of the selection switches 28 controlled by respective ones of the control bits. The voltage comparator 30 and switch 32 are provided in the same manner as in FIG. 3. In this respect it can be appreciated that in operation the switch. 32 is closed, to discharge each of the charged ones of the capacitors 24, in each FCO cycle; in contrast the selection switches 28 have relatively constant or only slowly changing states.

It will be appreciated that a combination of the arrangements of FIGS. 3 and 4, using a plurality of weighted current sources and a plurality of weighted capacitances and respective selection switches, may alternatively be provided.

In each of these frequency controlled oscillator arrangements, it can be appreciated that the time required for the capacitor(s) to reach the threshold voltage of the comparator 30, and hence the frequency of pulses produced at the output of the comparator 30, is dependent upon the selected capacitance and current, determined by the respective control bits supplied to the selection switches 28.

FIG. 5 illustrates another modification of the frequency controlled oscillator of FIG. 3, in which the capacitor 24 is charged by one set of (in this case three) binary weighted current sources 26 selected by switches 28, and is discharged (or charged with an opposite polarity) by another set of similar binary weighted current sources 27 selected by switches 29. The voltage to which the capacitor 24 is charged is supplied to a comparator with hysteresis, the output of which constitutes the output of the frequency controlled oscillator and, used directly and inverted by an inverter 34, serves to alternately enable and disable the sets of switches 28 and 29, the switches of both sets being controlled by respective control bits. This arrangement of FIG. 5 may be preferred for providing an approximately 50% duty cycle of the output of the frequency controlled oscillator and a reduced error similar to that for a dual slope analog-to-digital converter.

A plurality of capacitors 24 with binary weighted capacitances, as described above with reference to FIG. 4, can also be provided in the frequency controlled oscillator of FIG. 5.

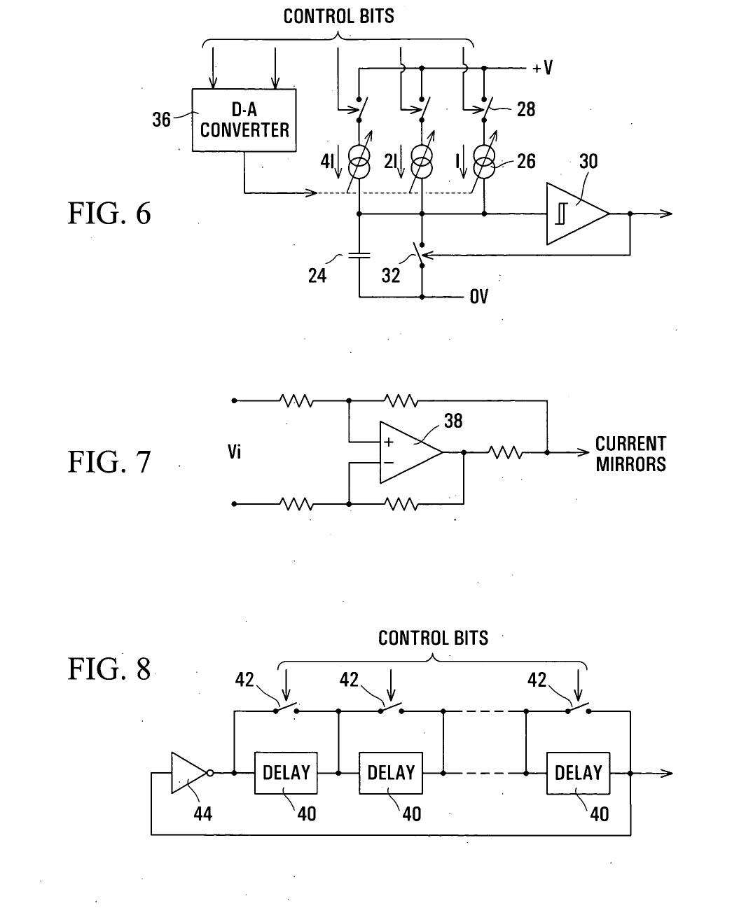

FIG. 6 illustrates a modified form of frequency controlled oscillator, based on the form of the frequency controlled oscillator of FIG. 3; modifications such as those described above with reference to FIGS. 4 and 5 are also applicable to the frequency controlled oscillator of FIG. 6.

The frequency controlled oscillator of FIG. 6 is similar to that of FIG. 3 except in that the binary weighted current sources 26, three of which are illustrated in FIG. 6 and are selected by respective switches 28 in response to respective control bits, are also controlled to provide variable currents (maintaining the binary weighting) in dependence upon an output of a D-A (digital to analog) converter or DAC 36 which is controlled with further ones of the control bits, two control bits as illustrated in FIG. 6. Thus in the frequency controlled oscillator of FIG. 6 the magnitude of the current I is determined by the control bits supplied to the DAC 36.

By way of example, FIG. 7 illustrates a voltage-to-current converter, also known as a Norton current source, which may be used in the frequency controlled oscillator of FIG. 6 to provide a variable current I, comprising a differential amplifier 38 and a resistor network. An input voltage Vi to the converter of FIG. 7 can for example be constituted by the output of the DAC 36 of FIG. 6, by the input voltage Vin of the switch mode regulator controlled by the PWM arrangement, or by a voltage derived from this voltage Vin. An output current of the converter of FIG. 7 represents the current I and is mirrored to a plurality of current mirrors (not shown) to produce the controlled binary weighted currents I, 2I, and 4I represented in the frequency controlled oscillator of FIG. 6.

It can therefore be appreciated that although FIG. 6 shows the DAC 36 as providing an output for controlling the binary weighted currents I, 2I, and 4I, this need not be the case. Instead, the DAC 36 can be omitted and the binary weighted currents I, 2I, and 4I can be controlled by an analog voltage, such as the input voltage Vin of a switch mode regulator controlled by the PWM arrangement. Similarly, other control bits may be replaced by analog equivalents, so that the PWM arrangement can be controlled by all digital control bits or by an arbitrary combination of analog and digital signals.

In particular, controlling the magnitude of the current provided by the or each current source in dependence upon the input voltage Vin of a switch mode regulator controlled by the PWM arrangement, whether this control is provided in a digital and/or an analog manner, provides an advantage of compensating for variation of this input voltage over a potentially wide range (for example, greater than 2:1 for the variation from 7V to 15V discussed above). This feed forward control arrangement gives the desirable result, especially for a buck regulator, that a product of the output duty factor of the PWM arrangement and the input voltage Vin is substantially constant.

Thus in particular a PWM arrangement in accordance with an embodiment of the invention can have a frequency controlled oscillator 20 with one or more current sources controlled in a digital or analog manner in dependence upon an input voltage of a switch mode regulator controlled by the PWM arrangement, and a counter 22 controlled by all or some (others also controlling the frequency controlled oscillator 20) of the bits of a digital control word representing a feedback control signal (voltage and/or current) for controlling the switch mode regulator.

In the arrangements of FIGS. 2 to 7 as described above, it is assumed by way of example that the control bits and/or analog control signals supplied to the frequency controlled oscillator 20 and/or the counter 22 are derived from an error feedback voltage and optionally an input voltage, but this need not be the case. Current mode control of the PWM arrangement can alternatively or additionally be provided, and/or the PWM arrangement can be used in an open loop configuration.

Thus generally, the digital PWM arrangement can provide any desired combination of current and/or voltage feed-forward and/or feedback control, using any desired digital and/or analog control signals.

As indicated above, conceivably the counter 22 can be omitted entirely from the digital PWM arrangement of FIG. 2, the pulsed output of the frequency controlled oscillator 20 being used directly to reset the flip-flop 14. This is more practical for relatively lower required resolution of the PWM control, for example in the event that the digital control word only requires about 6 bits to provide the desired PWM resolution. For a larger number of bits of the control word, providing a greater resolution, it is generally more convenient to provide the counter 22 than to provide large ratios of binary weighted current sources. For example, whereas for a 6-bit control word with the arrangement of FIG. 3 and in the absence of the counter 22 it may be practical for the current sources 26 to provide currents in ratios from 32:1 (currents I, 2I, 4I, 8I, 16I, and 32I controlled by respective ones of the 6 control bits), for an 8-bit control word this ratio is increased to 128:1 for which providing currents may be considerably less practical than providing the counter 22. However, in general it can be appreciated that the counter 22 may be absent, or can comprise a counter of any number of bits less than the size of the digital control word.

Although particular types of frequency controlled oscillator 20 are described above, it can be appreciated that the frequency controlled oscillator 20 can have any other desired form. By way of example, FIG. 8 illustrates another form of frequency controlled oscillator which may be used in the arrangement of FIG. 2.

Referring to FIG. 8, the frequency controlled oscillator shown therein comprises a plurality of delay stages 40, each of which is selectively bypassed by a respective one of a like plurality of switches 42 which are controlled by respective bits of the control word. The delay stages 40 are connected in series in a chain, an output of the last delay stage 40 constituting an output of the frequency controlled oscillator and being connected via an inverter 44 to an input of the first delay stage 40. Consequently, the frequency of the frequency controlled oscillator is determined by the selective bypassing of the delay stages 40 and hence controlled by the switches 42. The delay stages 40 can conveniently provide binary weighted delays. Each delay stage 40 can for example be constituted by a propagation delay through a respective plurality of buffers or (an even number of) inverters.

Although embodiments of the invention are described above in the context of a digital PWM arrangement, the invention is not limited in this respect but is also applicable to other digital pulse modulation schemes, such as pulse position modulation (PPM) and phase shift modulation (PSM) of a pulsed signal.

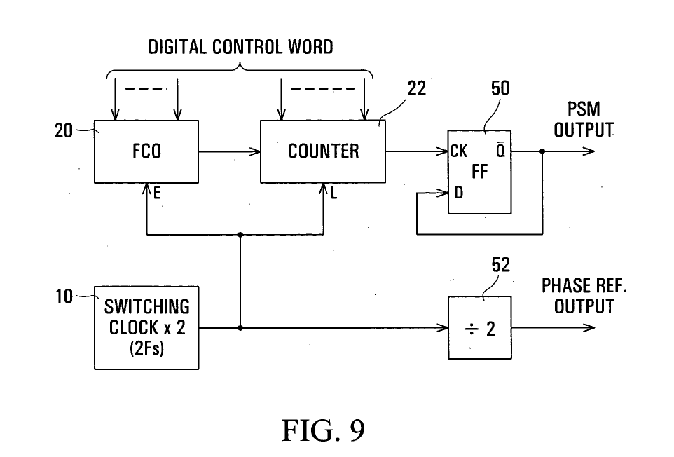

By way of example, FIG. 9 schematically illustrates a digital PSM arrangement which includes a frequency controlled oscillator (FCO) 20 and a counter 22 controlled by bits of a digital control word in a similar manner to the digital PWM arrangement of FIG. 3. The various modifications described above with respect to FIGS. 4 to 8 can also be applied to the digital PSM arrangement of FIG. 9.

In addition, the digital PSM arrangement of FIG. 9 includes a clock source 10, in this case operating at a frequency of 2Fs which is twice the desired switching frequency of a PSM output signal of the arrangement, a D-type flip-flop (FF) 50, and a frequency divider 52. The output of the clock source 10 is frequency-divided by 2 by the frequency divider 52, to produce a square waveform (50% duty cycle) phase reference output signal at the frequency Fs.

The output of the clock source 10 is also supplied to an enable input of the FCO 20 and to a load input L of the counter 22, which operate in a similar manner to that described above to produce a frequency controlled oscillator signal, and to frequency divide it by counting in the counter, in accordance with the digital control word supplied to the FCO 20 and the counter 22. Consequent transitions at the output of the counter 22 are supplied to a clock input CK of the flip-flop 50, which has its inverting output \overline{Q} connected to its data input D to change state with each pulse at its clock input CK. Consequently, a phase shift modulation (PSM) output signal of the arrangement of FIG. 9, constituted by the \overline{Q} output of the flip-flop 50, is a square wave at the same frequency Fs as the phase reference output but delayed, i.e. phase shifted, relative to the phase reference signal. The phase shift is determined by the digital control word supplied to the FCO 20 and the counter 22 in the same manner as that described above with reference to FIG. 3.

Although particular embodiments of the invention and variations and applications have been described above in detail, it can be appreciated that these and numerous other modifications, variations, and adaptations may be made without departing from the scope of the invention as defined in the claims.

1. A pulse modulation arrangement comprising a clock signal for determining a frequency of a pulse modulation signal and apparatus for determining a modulation parameter of the pulse modulation signal, the apparatus for determining a modulation parameter of the pulse modulation signal comprising a frequency controlled source responsive to a pulse modulation control signal.

2. A pulse modulation arrangement as claimed in claim 1 wherein the apparatus for determining a modulation parameter of the pulse modulation signal further comprises a counter for counting pulses produced by the frequency controlled source.

3. A pulse modulation arrangement as claimed in claim 2 wherein the counter is controllable for counting a controlled number of pulses produced by the frequency controlled source for determining the modulation parameter of the pulse modulation signal.

4. A pulse modulation arrangement as claimed in claim 3 wherein the pulse modulation control signal comprises a digital control signal.

5. A pulse modulation arrangement as claimed in claim 4 wherein the frequency controlled source comprises a plurality of binary weighted elements and a plurality of switches for selecting said binary weighted elements in dependence upon respective bits of said digital control signal.

6. A pulse modulation arrangement as claimed in claim 5 wherein the binary weighted elements comprise current sources.

7. A pulse modulation arrangement as claimed in claim 5 wherein the binary weighted elements comprise capacitors.

8. A pulse modulation arrangement as claimed in claim 5 wherein the binary weighted elements comprise delay elements.

9. A pulse modulation arrangement as claimed in claim 1 wherein the pulse modulation control signal comprises a digital control signal.

10. A pulse modulation arrangement as claimed in claim 9 wherein the frequency controlled source comprises a plurality of binary weighted elements and a plurality of switches for selecting said binary weighted elements in dependence upon respective bits of said digital control signal.

11. A pulse modulation arrangement as claimed in claim 10 wherein the binary weighted elements comprise current sources.

12. A pulse modulation arrangement as claimed in claim 10 wherein the binary weighted elements comprise capacitors.

13. A pulse modulation arrangement as claimed in claim 10 wherein the binary weighted elements comprise delay elements.

14. A pulse modulation arrangement as claimed in claim 1 wherein the frequency controlled source comprises at least one current source for providing a current with a magnitude controlled by a control signal.

15. A pulse modulation arrangement as claimed in claim 1 wherein the modulation parameter comprises a pulse width of the pulse modulation signal.

16. A pulse modulation arrangement as claimed in claim 1 wherein the modulation parameter comprises a phase shift of the pulse modulation signal.

17. In combination, a pulse modulation arrangement as claimed in claim 1 and a switch mode regulator controlled by the pulse modulation arrangement, wherein a switching clock of the switch mode regulator is derived from the clock signal for, determining a frequency of the pulse modulation signal, and the pulse modulation control signal comprises a feedback control signal of the switch mode regulator.

18. The combination of claim 17 wherein the pulse modulation control signal further comprises a feed forward control signal dependent upon an input voltage of the switch mode regulator.

19. The combination of claim 18 wherein the feed forward control signal comprises a digital signal.

20. The combination of claim 18 wherein the feed forward control signal comprises an analog signal.
